(19) United States
(12) Patent Application Publication
(10) Pub. No.: US 2017/0062638 A1
(43) Pub. Date: Mar. 2, 2017

(54) SOLAR PANEL AND SYSTEM FOR PRODUCING CLEAN ENERGY

(71) Applicant: David Paul Oddoye, El Cerrito, CA (US)

(72) Inventor: David Paul Oddoye, El Cerrito, CA (US)

(21) Appl. No.: 14/843,854

(22) Filed: Sep. 2, 2015

(51) Int. Cl. H01L 31/042; H01L 31/12

(52) U.S. Cl. CPC H01L 31/042; H01L 31/12

(57) ABSTRACT

A solar panel system is disclosed which provides highly efficient solar conversion which is operable during the day, night, and low level sunlight. The system uses back illuminated electron multiplying charged coupled devices (bi-emccds) to efficiently convert sunlight signals into usable solar power. In an exemplary embodiment, the bi-emccds may be arranged according to a Fibonacci sequence to maximize the available sunlight incident on the panel.

### BACKGROUND

The embodiments herein relate generally to energy conversion systems, and more particularly to a solar panel and system for producing clean energy.

Conventional solar power generation systems convert only about 30 percent of the Sun's energy into electricity. Much of the signal from sunlight is lost in inefficient transfer and conversion of electron charge within a static solar cell. Moreover conventional solar power production is limited to only daylight hours. As a result, conventional solar power generation provides only about one-tenth of one percent of all electricity used in the world. Instead, most electricity is produced by fossil fuel run systems and hydroelectric plants both of which produce undesirable environmentally unfriendly waste. As can be seen, there is a need for solar generation that is both clean and operable during low sunlight.

### SUMMARY

According to one embodiment of the subject technology, a solar conversion system for producing clean energy comprises a panel; a plurality of back illuminated electron multiplying charged coupled devices (bi-emccds) in the panel for multiplying received solar energy into converted solar power; and an output for supplying the converted solar power to a load.

According to another embodiment of the subject technology, a solar conversion system for producing clean energy comprises a panel; a plurality of back illuminated charged coupled devices (bi-emccds) positioned end to end in an array in the panel for multiplying received solar energy along a string of the bi-emccds into converted solar power; and hydrolysis system coupled to an output of the plurality of back illuminated charged coupled devices (bi-emccds).

### BRIEF DESCRIPTION OF THE FIGURES

The detailed description of some embodiments of the present invention is made below with reference to the accompanying figures, wherein like numerals represent corresponding parts of the figures.

FIG. 1 is a schematic of a system for producing clean energy in accordance with an exemplary embodiment of the subject technology.

FIG. 2 is a front view of a solar panel system in accordance with an exemplary embodiment of the subject technology.

FIG. 3 a partial cross-sectional side view of the interior of the solar panel of FIG. 2 in accordance with an exemplary embodiment of the subject technology.

FIG. 4 is a side view of the system of FIG. 2.

FIG. 5 is a rear view of the system of FIG. 2.

### DETAILED DESCRIPTION OF CERTAIN EMBODIMENTS

Broadly, embodiments of the subject technology provide a system for producing clean energy that converts more sunlight into solar power. In addition, embodiments also provide a source of power at nighttime when sunlight is unavailable. Thus the subject technology may produce clean electricity at all hours regardless of the presence of the Sun.

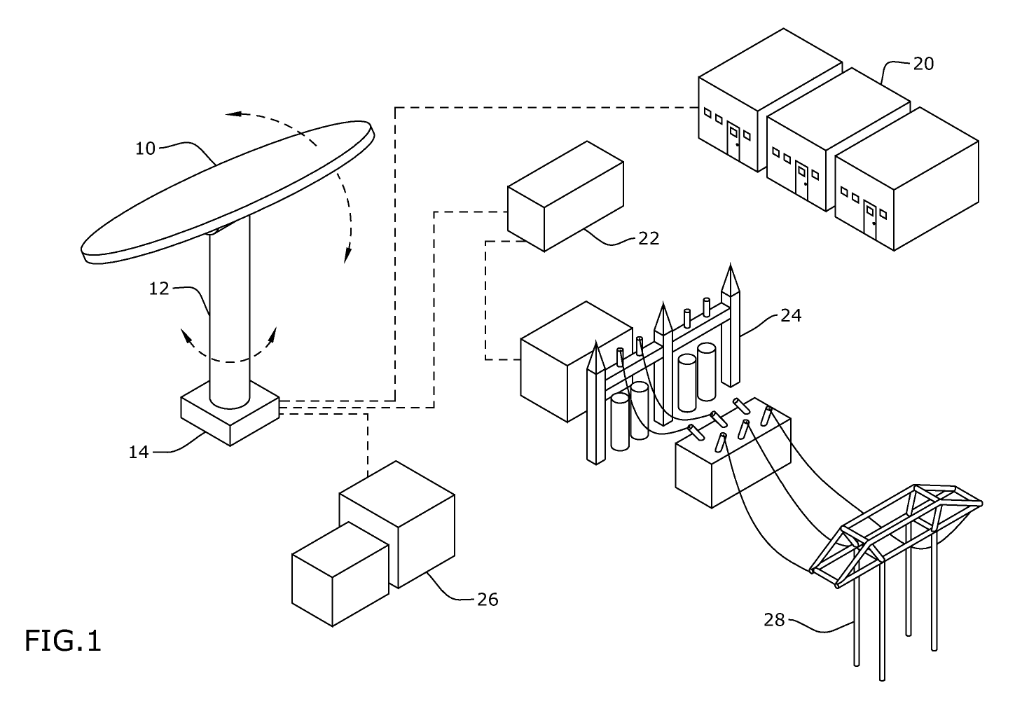

Referring now to FIG. 1, a solar conversion system for producing clean energy is shown according to an exemplary embodiment of the subject technology. The system includes a solar panel system 10 mounted in some embodiments to a stand 12 and base 14. The solar panel system 10 may be used in an outdoor environment to generate solar power by gathering sunlight. In an exemplary embodiment, the solar panel system 10 is connected to and providing power to one or more loads. For example, the solar panel system 10 may provide electrical power to an electrical grid 28 through one or more inverter systems 22 and a switchyard 24. The solar panel system 10 may also provide electrical power to a hydrolysis generating plant 20 for generation of electrical power. Some of the generated solar power may be used to generate stored power produced by the hydrolysis generating plant 20 as is known in the art of hydrolysis. During the night (or during times of insufficient sunlight), stored power in the hydrolysis generating plant 20 may be supplied to the solar panel system 10 to generate solar power as described more fully below.

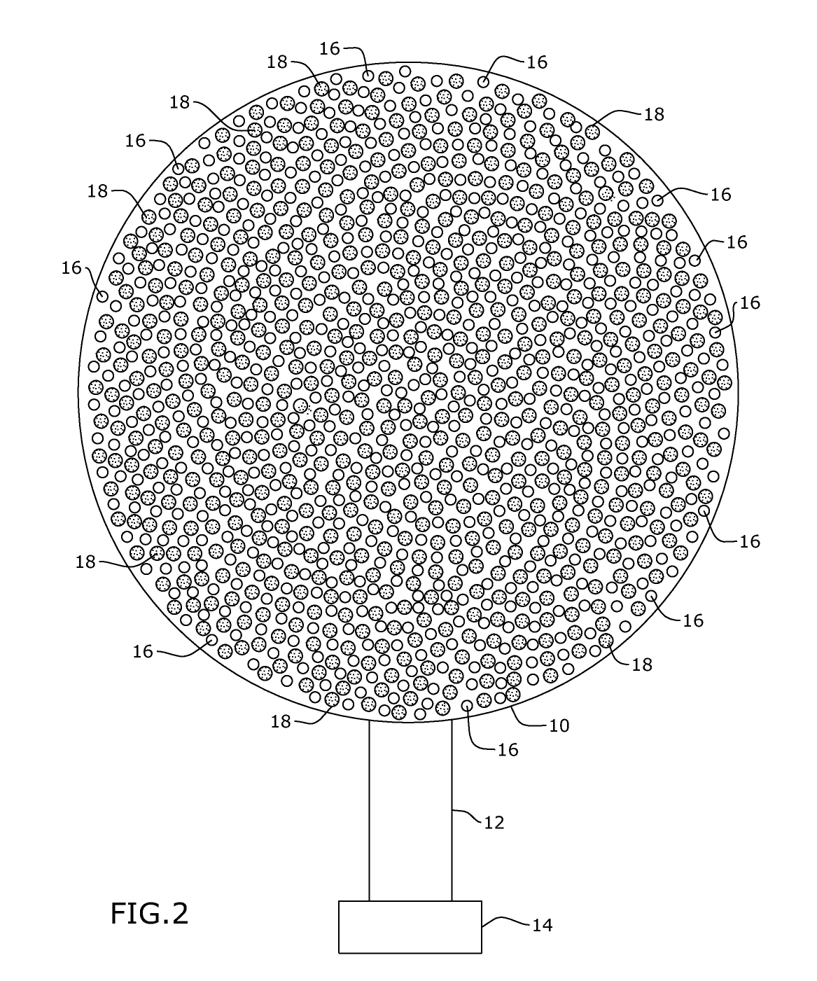

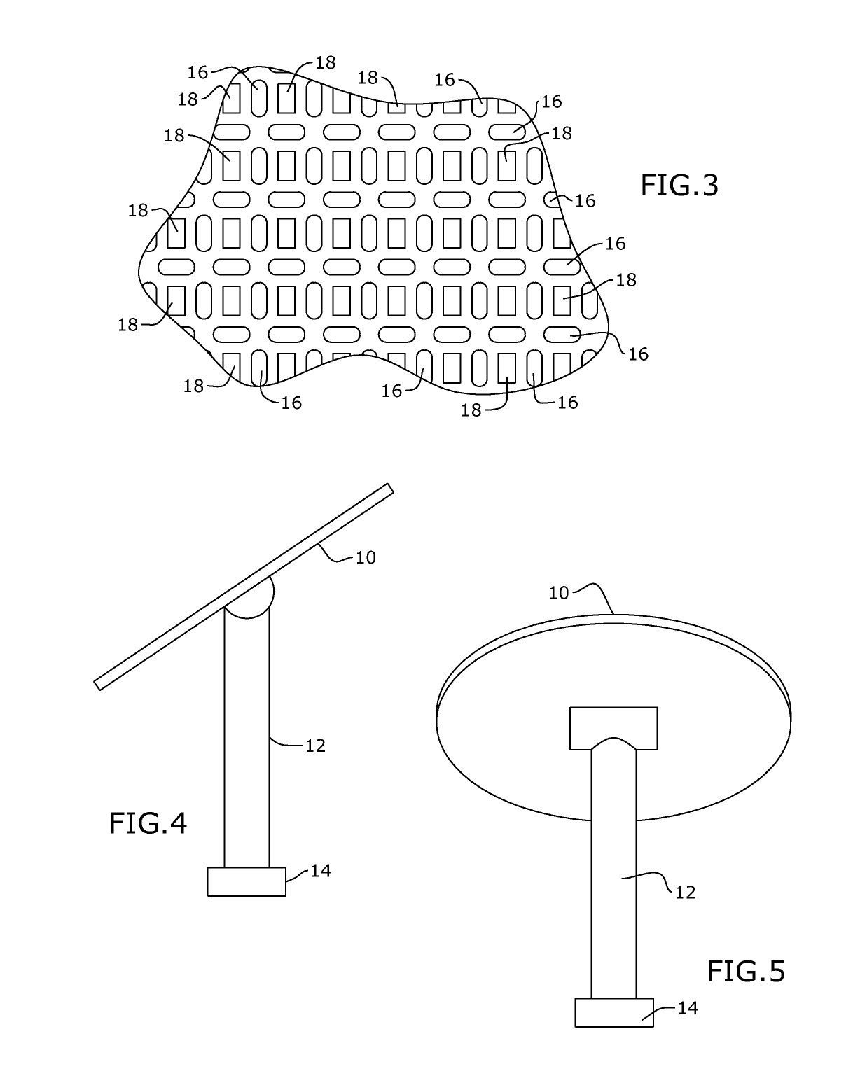

Referring now to FIGS. 2-5, details of the solar panel system 10 are shown. The solar panel system 10 includes a plurality of back illuminated electron multiplying charged coupled devices (bi-emccds) 18 positioned in an array in the panel for multiplying received solar energy along a string of the bi-emccds into converted solar power. By using bi-emccds 18, the subject technology may more efficiently convert available sunlight into usable solar power. The bi-emccds 18 collect and multiply electron charges from the solar sunlight signal so that even normally weak signals that conventional solar cells are unable to convert are registerable by the bi-emccds 18. Thus the range of usable sunlight is expanded into a usable signal for conversion into solar power. In some embodiments, the bi-emccds 18 are full spectral types capable of harvesting solar energy from the infra-red to the near-ultraviolet wavelengths of the electromagnetic spectrum. An exemplary embodiment of the solar panel system 10 has the bi-emccds 18 arranged end to end forming layers of bi-emccds (see for example, FIG. 3) providing multiple stages of photonic receipt and conversion through the depth of the panel. The multiple stages may amplify weak signals down the line further aiding in harvesting usable solar signals for conversion. Another exemplary embodiment has the bi-emccds 18 arranged according to the Golden Angle following a Fibonacci sequence. As may be appreciated, such an embodiment may be superior over solar panel cell arrangements which use linear grids because the bi-emccds are arranged to maximize the space potential within the panel space. Thus more sunlight may be captured and converted. The efficiency of embodiments of the solar panel system 10 may be in the range of 80%-99%. As may be appreciated, this is a significant increase in performance when compared to conventional solar panel systems.

Referring back to FIG. 1 concurrently with FIG. 2, an embodiment of the solar panel system 10 may include a plurality of LEDs 16 interspersed among the bi-emccds 18. The LEDs 16 may supply an auxiliary light source to the bi-emccds 18 which may be useful during times of low sunlight availability. The LEDs 16 may be for example side illuminating LEDs whose light output may be registerable by at least a first layer of the bi-emccds 18. As described above, the power for the LEDs 16 may be supplied by stored power generated by the hydrolysis generating plant 20. As may be appreciated, the process for generating and storing electricity in the hydrolysis generating plant 20 is an environmentally clean and friendly process whose primary waste is clean oxygen which may be safely released into the atmosphere and helps clean the breathable air in the area. The light from the LEDs 16 exceed the electrical threshold frequency generated by hydrogen fuel cells in the hydrolysis generating plant 22 to supply the electricity needed to turn on the LEDs 16. As a result, the bi-emccds 18 may efficiently convert the light from already efficient LEDs 16 into clean power supplied to the grid 28 without the harmful effects normally associated with fossil fuel based electrical production.

The word “exemplary” is used herein to mean “serving as an example or illustration.” Any aspect or design described herein as “exemplary” is not necessarily to be construed as preferred or advantageous over other aspects or designs.

Persons of ordinary skill in the art may appreciate that numerous design configurations may be possible to enjoy the functional benefits of the inventive systems. Thus, given the wide variety of configurations and arrangements of embodiments of the present invention the scope of the present invention is reflected by the breadth of the claims below rather than narrowed by the embodiments described above.

What is claimed is:

1. A solar conversion system for producing clean energy, comprising:
a panel;
a plurality of back illuminated electron multiplying charged coupled devices (bi-emccds) in the panel for multiplying received solar energy into converted solar power; and
an output for supplying the converted solar power to a load.

2. The system of claim 1, further comprising a plurality of LEDs interspersed between the plurality of bi-emccds for supplying an auxiliary light source to the bi-emccds.

3. The system of claim 1, wherein the plurality of bi-emccds are arranged in a pattern following a Fibonacci sequence.

4. The system of claim 1, wherein the plurality of bi-emccds are arranged end to end in a plurality of stages.

5. A solar conversion system for producing clean energy, comprising:
a panel;
a plurality of back illuminated charged coupled devices (bi-emccds) positioned end to end in an array in the panel for multiplying received solar energy along a string of the bi-emccds into converted solar power; and
hydrolysis system coupled to an output of the plurality of back illuminated charged coupled devices (bi-emccds).

6. The system of claim 5, further comprising a plurality of LEDs interspersed between the plurality of bi-emccds for supplying an auxiliary light source to the bi-emccds to power the hydrolysis system at night.

7. The system of claim 5, wherein the plurality of bi-emccds are arranged in a pattern following a Fibonacci sequence.

8. The system of claim 5, wherein the plurality of bi-emccds are arranged end to end in a plurality of stages.
